(19) United States
(12) Patent Application Publication
(10) Pub. No.: US 2009/0206733 A1
(43) Pub. Date: Aug. 20, 2009

(54) ORGANIC LIGHT EMITTING DIODE DISPLAY AND METHOD OF MANUFACTURING THE SAME

(75) Inventors: Young-In HWANG, Yongin-si (KR); Baek-Woon LEE, Yongin-si (KR); Hae-Yeon LEE, Bucheon-si (KR); Young-Gu JU, Daegu-si (KR)

Correspondence Address: CANTOR COLBURN, LLP, 20 Church Street, 22nd Floor, Hartford, CT, 06103, US

(73) Assignees: SAMSUNG ELECTRONICS CO., LTD., Suwon-si (KR); Kyungpook National University Industry-Academic Cooperation Foundation, Daegu-si (KR)

(21) Appl. No.: 12/111,639

(22) Filed: Apr. 29, 2008

(30) Foreign Application Priority Data
Feb. 18, 2008 (KR) 10-2008-0014544

(51) Int. Cl. H01L 27/32; H01J 9/02

(52) U.S. Cl. 313/504; 445/24

(57) ABSTRACT

An organic light emitting diode (OLED) display and a method of manufacturing the same are disclosed. The OLED display includes a first pixel, a second pixel, and a third pixel that display different colors. The display includes a first electrode, a second electrode that is opposite to the first electrode, and an emission layer which is disposed between the first electrode and the second electrode. A semi-transparent member is positioned on or under the first electrode and forms a microcavity together with the second electrode. An overcoating film is positioned under the semi-transparent member. At least one of the first pixel, the second pixel, and the third pixel has embossings formed in a surface of the semi-transparent member.

This application claims priority to Korean Patent Application No. 10-2008-0014544 filed on Feb. 18, 2008, and all the benefits accruing therefrom under 35 U.S.C. §119, the contents of which in its entirety are incorporated herein by reference.

### BACKGROUND OF THE INVENTION

1. Field of the Invention

The present invention relates to an organic light emitting diode display and a method of manufacturing the same.

2. Description of the Related Art

Currently, a decrease in weight and thickness of monitors, televisions, etc., is requested, and according to such a request, cathode ray tubes (“CRTs”) are being replaced with liquid crystal displays (“LCDs”).

However, since the LCD is a light-receiving type device, it requires a separate light source such as backlight, and the LCD has a limitation in response speed and viewing angle.

As a display device which can overcome the limitation, an organic light emitting diode display (“OLED” display) has been in the spotlight.

The OLED display includes two electrodes and an emission layer which is sandwiched therebetween, and it forms excitons by combining electrons which are injected from one electrode and holes which are injected from another electrode in the emission layer and emits light as excitons release energy.

Because the OLED display is a self-light emitting type, the OLED display does not require a separate light source, whereby it is advantageous in power consumption and has an excellent response speed, viewing angle, and contrast ratio.

The OLED display includes a plurality of pixels such as a red pixel, a blue pixel, and a green pixel, and expresses full colors by combining the pixels.

However, the OLED display has different light-emitting efficiency according to light emitting materials. That is, among a red color, a green color, and a blue color, a material having low light-emitting efficiency cannot express a color of a desired color coordinate. Even when emitting light of a white color by combining a red color, a green color, and a blue color, desired white color light cannot be emitted due to the color having low light-emitting efficiency. Therefore, because a range of a color which can express is limited, color reproducibility is deteriorated.

Light which is emitted from an emission layer is discharged to the outside through a substrate and a plurality of thin films such as an electrode and an insulating layer. Due to an interface between the substrate and the thin films or total reflection in a substrate surface, the light which is discharged to the outside is only about 20% of light which is emitted from the emission layer. Accordingly, light-emitting efficiency is deteriorated, leading to a decrease in the luminance.

In the OLED display, due to a limitation in the light emitting material and light-emitting efficiency, color reproducibility and luminance may be deteriorated.

As a solution to this, a microcavity has been proposed.

As light is repeatedly reflected from a reflective layer and a semi-transparent layer which are apart from each other by a predetermined gap (hereinafter referred to as an “optical path length”), a strong interference effect is generated between the light. The microcavity effect may be described by a principle in which light of a specific wavelength is amplified and light of other wavelengths is attenuated.

Accordingly, in the front view, luminance is improved and color reproducibility also increases.

However, in order to express a full color while using the microcavity, a red pixel, a green pixel, and a blue pixel should have an optical path length corresponding to a wavelength of each pixel. In order to form a microcavity having a different optical path length in each pixel, a process for adjusting an optical path length should be performed for each pixel and thus the number of process steps increases.

Further, because luminance and color reproducibility are set based on the front view, a color shift may be generated in the microcavity according to a viewing angle.

### BRIEF SUMMARY OF THE INVENTION

The present invention has been made in an effort to provide an organic light emitting diode display and a method of manufacturing the same having advantages of simplifying a process which is required for forming a microcavity, and increasing luminance and color reproducibility in the front view and the side view.

According to an exemplary embodiment of the invention, the invention provides an organic light emitting diode (OLED) display device comprising a plurality of pixels. The display device comprises: a first electrode; a second electrode which is opposite to the first electrode; an emission layer which is disposed between the first electrode and the second electrode; a semi-transparent member is positioned on or under the first electrode and forms a microcavity together with the second electrode; and an overcoating film that is positioned under the semi-transparent member, wherein at least one of the pixels includes embossings formed in a surface of the overcoating film, the embossings forming a flexural surface having a tilt angle.

According to an exemplary embodiment, the pixel includes a green pixel, a blue pixel and a red pixel.

According to an exemplary embodiment, the embossings are formed in the green pixel.

According to an exemplary embodiment, the embossings are formed in the red pixel and the blue pixel.

According to an exemplary embodiment, the embossings are formed in the green pixel, the red pixel and the blue pixel, and the tilt angle of the embossings formed in the green pixel is different from that of that embossings formed in the red pixel and the blue pixel.

According to an exemplary embodiment, the tilt angle of the embossings formed in the green pixel is greater than that of the embossings formed in the red pixel and the blue pixel.

According to an exemplary embodiment, the embossings formed in the red pixel and in the blue pixel have substantially identical tilt angles.

According to an exemplary embodiment, the emission layer includes a plurality of sub-emission layers which emit light of different wavelengths and emits white light by combining the light of the different wavelengths.

According to an exemplary embodiment, the OLED display device further comprises a color filter that is formed in the pixel.

According to an exemplary embodiment, the semi-transparent member comprises N number of layers including a first layer and a second layer are alternately stacked, the first and second layers having different refractive indexes.

According to an exemplary embodiment, the semi-transparent member has a substantially uniform thickness in each of the plurality of pixels, and the thicknesses of the first layer and the second layer in N−1 number of layers are λ/4n₁ and λ/4n₂, respectively (n₁ is a refractive index of the first layer, n₂ is a refractive index of the second layer, and λ is a wavelength of a green region).

According to an exemplary embodiment, the first layer comprises silicon oxide (SiO₂), and the second layer comprises silicon nitride (SiNₓ).

According to an exemplary embodiment, the semi-transparent member has a substantially uniform thickness, and when a gap between the second electrode and the semi-transparent member is an optical path length (L), the optical path length is the smallest value among values satisfying both L=m₁λ₁/2 and L=m₂λ₂/2 (λ₁ is a wavelength of a red region, λ₂ is a wavelength of a blue region, and m₁ and m₂ are natural numbers).

According to an exemplary embodiment, the pixel further includes a white pixel, wherein the overcoating film is not formed in the white pixel.

According to an exemplary embodiment of the invention, the invention provides a method of manufacturing an OLED display device having a plurality of pixels. The method includes forming a plurality of thin film transistors on a substrate, forming an overcoating film on the substrate and the thin film transistor, forming embossings in a surface of the overcoating film, the embossings having a tilt angle; forming a semi-transparent member on the overcoating film; forming a first electrode on the semi-transparent member, forming an emission layer on the first electrode, and forming a second electrode on the emission layer.

According to an exemplary embodiment, the forming of embossings in a surface of the overcoating film includes disposing a mask having an opening on the overcoating film and exposing, and performing heat treatment of the exposed overcoating film.

According to an exemplary embodiment, the pixel includes a green pixel, a red pixel and a blue pixel.

According to an exemplary embodiment, the embossings are formed in the green pixel.

According to an exemplary embodiment, the embossings are formed in the red pixel and the blue pixel.

According to an exemplary embodiment, the embossings are formed in the green pixel, the red pixel, and the blue pixel, and the tilt angle of embossings formed in the green pixel is different from that of the embossings formed in the red pixel and the blue pixel.

According to an exemplary embodiment, the tilt angle is adjusted by varying an exposure amount.

According to an exemplary embodiment, the tilt angle is adjusted by varying the size of openings of the mask.

According to an exemplary embodiment, the forming of embossings in a surface of the overcoating film includes forming a contact hole which exposes a part of the thin film transistor in the overcoating film.

According to an exemplary embodiment, the pixel further includes a white pixel, and wherein the forming of embossings in a surface of the overcoating film comprises removing the overcoating film which is formed in the white pixel.

According to an exemplary embodiment of the invention, the invention provides a light emitting display device having a plurality of pixels. The display device includes a first electrode, a second electrode which is opposite to the first electrode; an emission layer which is disposed between the first electrode and the second electrode, a semi-transparent layer which forms a microcavity with the second electrode, wherein the semi-transparent layer includes a flexural surface, the flexural surface being inclined with respect to the plane of the semi-transparent layer.

According to an exemplary embodiment, the pixel includes a green pixel, a blue pixel and a red pixel, and the flexural surface is formed in the green pixel.

### BRIEF DESCRIPTION OF THE DRAWINGS

The above and/or other aspects, features and advantages of the present invention will become more apparent from the following detailed description when taken in conjunction with the accompanying drawings, in which:

FIG. 1 is an equivalent circuit diagram of an exemplary embodiment of an OLED display according to the present invention;

FIG. 2 is a top plan view illustrating a disposition of a plurality of pixels in an exemplary embodiment of an OLED display according to the present invention;

FIG. 3 is a cross-sectional view of an exemplary embodiment of an OLED display according to the present invention;

FIG. 4 is a cross-sectional view illustrating an exemplary embodiment of an OLED display according to the present invention;

FIGS. 5 to 12 are cross-sectional views sequentially illustrating an exemplary embodiment of a method of manufacturing the OLED display of FIG. 4 according to of the present invention;

FIG. 13 is a cross-sectional view illustrating an exemplary embodiment of an OLED display according to the present invention;

FIG. 14 is a cross-sectional view illustrating an exemplary embodiment of an OLED display according to the present invention;

FIG. 15 is a schematic diagram illustrating an exemplary embodiment of a semi-transparent member according to the present invention;

FIG. 16 is a schematic diagram illustrating a plurality of microholes which are formed in a semi-transparent unit of a mask;

FIG. 17 is a diagram illustrating the change of a tilt angle of embossings according to an exposure amount;

FIG. 18 is a graph illustrating a light emitting spectrum in a front view and a side view of a red pixel R and a blue pixel B in an exemplary embodiment of an OLED display according to the present invention;

FIG. 19 is a graph illustrating a light emitting spectrum in a front view and a side view of a green pixel G in an exemplary embodiment of an OLED display according to the present invention;

FIG. 20 is a graph illustrating color reproducibility of an exemplary embodiment of an OLED display according to the present invention;

FIG. 21 is a graph illustrating a light emitting spectrum in a front view and a side view of a red pixel R and a blue pixel B in an exemplary embodiment of an OLED display according to the present invention;

FIG. 22 is a graph illustrating a light emitting spectrum in a front view and a side view of a green pixel G in an exemplary embodiment of an OLED display according to the present invention;

FIG. 23 is a graph illustrating color reproducibility of an exemplary embodiment of an OLED display according to the present invention;

FIG. 24A is a graph illustrating a spectrum of light passing through a white pixel W when an overcoating film and a lower insulating layer are formed in the white pixel W according to an exemplary embodiment of the present invention; and

FIG. 24B is a graph illustrating a spectrum of light passing through a white pixel W when an overcoating film and a lower insulating layer are not formed in the white pixel W according to an exemplary embodiment of the present invention.

### DETAILED DESCRIPTION OF THE EMBODIMENTS

The invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. Like reference numerals refer to like elements throughout.

It will be understood that when an element is referred to as being “on” another element, it can be directly on the other element or intervening elements may be present therebetween. In contrast, when an element is referred to as being “directly on” another element, there are no intervening elements present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower”, can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments of the present invention are described herein with reference to cross section illustrations that are schematic illustrations of idealized embodiments of the present invention. As such, variations from the shapes of the illustrations as a result, for example, of manufacturing techniques and/or tolerances, are to be expected. Thus, embodiments of the present invention should not be construed as limited to the particular shapes of regions illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present invention.

Hereinafter, the present invention will be described in detail with reference to the accompanying drawings.

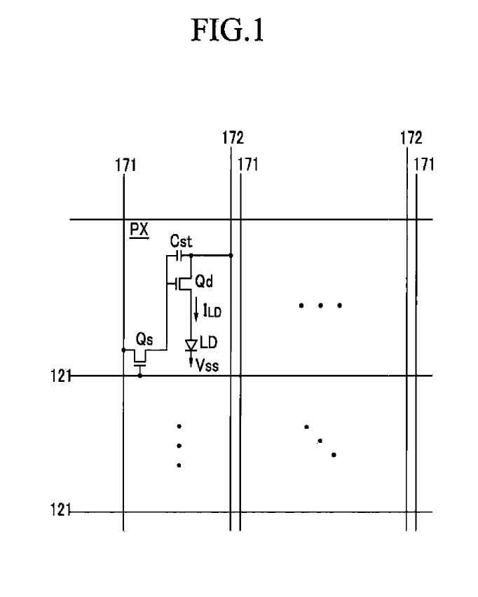

An OLED display according to an exemplary embodiment of the present invention is now described in detail with reference to FIG. 1.

FIG. 1 is an equivalent circuit diagram of an exemplary embodiment of an OLED display according to the present invention.

Referring to FIG. 1, the OLED display according to an exemplary embodiment of the present invention includes a plurality of signal lines 121, 171, and 172 and a plurality of pixels PX connected thereto which are arranged in a matrix form.

The signal lines include a plurality of gate lines 121 which transmits gate signals (or scanning signals), a plurality of data lines 171 which transmits data signals, and a plurality of driving voltage lines 172 which transmits driving voltages. The gate lines 121 extend in a row direction and are substantially parallel to each other, and the data lines 171 and the driving voltage lines 172 extend in a column direction and are substantially parallel to each other.

Each pixel PX includes a switching thin film transistor Qs, a driving thin film transistor Qd, a storage capacitor Cst, and an organic light emitting diode (“OLED”) LD.

Each switching thin film transistor Qs includes a control terminal, an input terminal, and an output terminal. The control terminal is connected to a gate line 121, the input terminal thereof is connected to a data line 171, and the output terminal is connected to a driving thin film transistor Qd via the storage capacitor Cst. A data signal is applied to the data line 171. The switching thin film transistor Qs transmits the data signal to the driving thin film transistor Qd in response to a scanning signal which is applied to the gate line 121.

The driving thin film transistor Qd includes a control terminal, an input terminal, and an output terminal. The control terminal is connected to the switching thin film transistor Qs, the input terminal is connected to the driving voltage line 172, and the output terminal is connected to the OLED LD. The driving thin film transistor Qd flows an output current I_{LD,} whose magnitude changes according to a voltage between the control terminal and the output terminal.

The capacitor Cst is connected between the control terminal and the input terminal of the driving thin film transistor Qd. The capacitor Cst charges a data signal which is applied to the control terminal of the driving thin film transistor Qd and sustains the charge even after the switching thin film transistor Qs is turned off.

The OLED LD includes an anode connected to the output terminal of the driving thin film transistor Qd and a cathode connected to a common voltage Vss. The OLED LD emits light with different intensity according to an output current I_{LD} of the driving thin film transistor Qd, thereby displaying an image.

The switching thin film transistor Qs and the driving thin film transistor Qd are n-channel field effect transistors (“FETs”). However, at least one of the switching thin film transistor Qs and the driving thin film transistor Qd may be a p-channel FET. Further, a connection relationship of the thin film transistors Qs and Qd, the capacitor Cst, and the OLED LD can be changed.

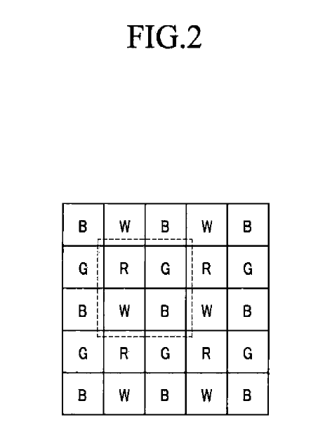

The OLED display shown in FIG. 1 is further described with reference to FIG. 2.

FIG. 2 is a top plan view illustrating a plurality of pixels in an exemplary embodiment of an OLED display according to the present invention.

Referring to FIG. 2, the OLED display includes a red pixel R which displays a red color, a green pixel G which displays a green color, a blue pixel B which displays a blue color, and a white pixel W which does not display a color. The above pixels are arranged in such a manner that neighboring red, green, blue and white pixels constitute a group and the group is repeated along a row and/or a column. However, the pixel arrangement can be varied depending on applications.

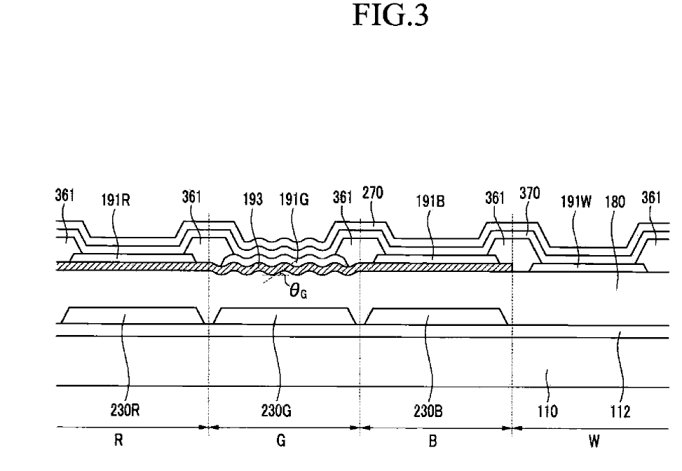

The OLED display of FIG. 2 is further described in detail with reference to FIG. 3.

FIG. 3 is a cross-sectional view illustrating a structure of an exemplary embodiment of an OLED display according to the present invention.

A plurality of thin film transistor arrays (not shown) is arranged on an insulating substrate 110. The thin film transistor array includes a switching thin film transistor (not shown) and a driving thin film transistor (not shown) which are disposed in each pixel. The switching thin film transistor and the driving thin film transistor are electrically connected to each other.

A lower insulating layer 112 is formed on the thin film transistor array and the substrate 110. A plurality of contact holes (not shown) which expose a part of the switching thin film transistor and the driving thin film transistor are formed in the lower insulating layer 112.

A red filter 230R, a green filter 230G, and a blue filter 230B are formed on the lower insulating layer 112 so as to correspond to the red pixel R, the green pixel G, and the blue pixel B, respectively. No color filter is formed in the white pixel, but a transparent filter (not shown) can be formed in the white pixel W. The color filters 230R, 230G, and 230B can be disposed in the form of a color filter on array (COA).

An overcoating film 180 is formed on the color filters 230R, 230G, and 230B and the lower insulating layer 112. A plurality of contact holes (not shown) are formed in the overcoating film 180.

The overcoating film 180 may be made of a photosensitive organic material such as an acryl-based compound. The overcoating film 180 provides a smooth surface while embedding the color filters 230R, 230G, and 230B.

Embossings are formed in the surface of the overcoating film 180 corresponding to the green pixel G, to thereby provide a plurality of flexures. The embossings can prevent a color shift according to a viewing angle by scattering light while changing a microcavity condition in the green pixel G. Details thereon are further described hereinafter.

Referring to FIG. 3, the embossings provide a plurality of flexural surfaces on the surface of the overcoating film. The flexural surfaces are inclined by a tilt angle θ_{G} with respect to the plane of the overcoating film 180.

A semi-transparent member 193 is formed on the overcoating film 180. Because the semi-transparent member 193 is formed along the surface flexure of the overcoating film 180, the semi-transparent member 193 of the green pixel G has a surface having flexures. The semi-transparent member 193 is formed in the red pixel R, the blue pixel B, and the green pixel G, but not in the white pixel W.

The semi-transparent member 193 transmits a part of light and reflects a part of light. The semi-transparent can employ distributed Bragg reflection (“DBR”) for adjusting reflexibility of a specific wavelength. The DBR may be made of a plurality of layers with different refractive indexes which are alternately stacked. However, the semi-transparent member 193 is not limited thereto, and may be formed of an opaque thin metallic layer such as silver (Ag) or aluminum (Al). The semitransparent member using the DBR is further described hereinafter.

A plurality of pixel electrodes 191R, 191G, 191B, and 191W are formed on the semi-transparent member 193. The pixel electrode 191G of the green pixel G has a surface having flexures along embossings which are formed in the surface of the overcoating film 180.

The pixel electrodes 191R, 191G, 191B, and 191W are respectively connected to driving thin film transistors through contact holes (not shown) which are formed in the overcoating film 180 and the lower insulating layer 112. The pixel electrodes 191R, 191G, 191B, and 191W may be made of a transparent conductor such as indium tin oxide (ITO) or indium zinc oxide (IZO).

An insulating layer 361 is formed on each of the pixel electrodes 191R, 191G, 191B, and 191W. The insulating layer 361 is formed in such a way to expose the pixel electrodes 191R, 191G, 191B, and 191W to contact edges of the pixel electrodes 191R, 191G, 191B, and 191W and includes a plurality of openings.

An organic emission layer 370 is formed on the insulating layer 361 and the pixel electrodes 191R, 191G, 191B, and 191W.

An auxiliary layer (not shown) for improving light emitting efficiency of the organic emission layer 370 may be further included at a lower part and/or an upper part of the organic emission layer 370. The auxiliary layer may include more than one which is selected from an electron transport layer, a hole transport layer, an electron injection layer, and a hole injection layer.

According to an exemplary embodiment, the organic emission layer 370 may be formed of a plurality of sub-emission layers (not shown) by sequentially stacking materials which intrinsically emit light of a red color, a green color, a blue color, etc., and emits white light by combining the colors. In this case, the sub-emission layers can be formed horizontally as well as vertically, and the organic emission layer is not limited to a combination of a red color, a green color, and a blue color, but can be formed of, for example, a combination of various other colors so long as it can emit white light.

The organic emission layer 370 which is positioned at the green pixel G has a surface having flexures along the embossings which are formed in the surface of the overcoating film 180.

A common electrode 270 is formed on the organic emission layer 370. The common electrode 270 may be made of a metal having high reflexibility. The common electrode 270 is formed on the entire surface of the organic emission layer 370 and constitutes a pair of electrodes together with the pixel electrodes 191R, 191G, 191B, and 191W to flow a current to the organic emission layer 370. The common electrode 270 which is positioned at the green pixel G has a surface having flexures along the embossings which are formed in a surface of the overcoating film 180.

The pixel electrodes 191R, 191G, 191B, and 191W, the organic emission layer 370, and the common electrode 270 constitute an OLED LD. The pixel electrodes 191R, 191G, 191B, and 191W serve as anodes and the common electrode 270 serves as a cathode, or vice versa.

The common electrode 270 generates a microcavity effect together with the semi-transparent member 193. The microcavity effect operates to amplify light of a specific wavelength by constructive interference as light is repeatedly reflected from a reflective layer and a semi-transparent layer which are spaced apart from each other by an optical path length. The common electrode 270 functions as a reflective layer and the semi-transparent member 193 functions as a semi-transparent layer.

The common electrode 270 greatly reforms light emitting characteristics of light which is emitted from the organic emission layer 370. Light around a wavelength corresponding to a resonance wavelength of a microcavity among the reformed light is reinforced through the semi-transparent member 193 and light of other wavelengths is suppressed. In this case, reinforcement and suppression of light of a specific wavelength can be determined according to the optical path length. The optical path length can be adjusted by changing the thickness of the semi-transparent member 193.

As described above, the semi-transparent member 193 may employ a DBR layer, and includes a plurality of layers which are made of inorganic materials having different refractive indexes which are alternately stacked. In a case where the semi-transparent member 193 is made of a plurality of layers made of inorganic materials, the semi-transparent member 193 can reduce loss of light when light transmits or is reflected, compared with a case where the semi-transparent member 193 is made of a metal such as Ag or Al.

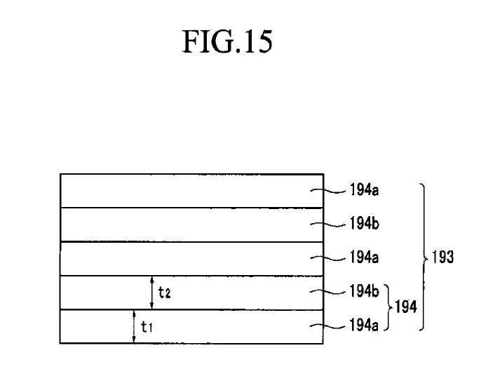

The semi-transparent member 193 using the DBR is further described with reference to FIG. 15.

FIG. 15 is a schematic diagram illustrating a semi-transparent member according to an exemplary embodiment of the present invention.

Referring to FIG. 15, the semi-transparent member 193 has a structure in which an inorganic layer 194 including a first layer 194a and a second layer 194b are multiply stacked, i.e., the first layer 194a and the second layer 194b are alternately and repeatedly stacked. The first layer 194a and the second layer 194b may be made of inorganic materials having different refractive indexes, for example the first layer 194a may be made of silicon oxide (SiO₂) having a refractive index of about 1.4 and the second layer 194b may be made of silicon nitride (SiNₓ) having a refractive index of about 1.6.

When it is assumed that an N number of first layers 194a and second layers 194b are stacked in total, the N−1 number of layers excepting one layer can have a fixed thickness at a specific wavelength regardless of a red pixel, a green pixel, and a blue pixel. For example, the N−1 number of layers can be fixed to a λ/4 thickness at a wavelength of a green region, and the thickness of the first and second layers can be determined as follows:

thickness t₁ of first layer=λ/4n₁ (1)

thickness t₂ of second layer=λ/4n₂ (2)

where n₁ is a refractive index of silicon oxide, n₂ is a refractive index of silicon nitride, and λ is a wavelength of a green region.

When a wavelength of a green region is about 530 nm, thicknesses t₁ and t₂ of the first layer 194a and the second layer 194b may be approximately 945 nm and about 830 nm, respectively.

In order to obtain a microcavity effect in each of the red pixel R, the green pixel G, and the blue pixel B, the optical path length is adjusted in each pixel. The optical path length can be adjusted by changing the thickness of the remaining layer excepting the N−1 number of layers among the N number of layers.

The thickness of the remaining layer can be formed such that the optical path length satisfies a constructive interference condition in both the red pixel R and the blue pixel B. Thus, the manufacturing process can be simplified.

An optical path length L which satisfies the constructive interference condition in both the red pixel R and the blue pixel B is represented by Equation (3):

L≈m λ₁/2≈(m+1)λ₂/2 (3)

where m is a natural number, λ₁ is a wavelength of a red region, and λ₂ is a wavelength of a blue region. In an exemplary embodiment of the present invention, the optical path length can be determined to the smallest value among values satisfying the constructive interference condition, and for example m≈2.

The optical path length which satisfies the constructive interference condition in both the red pixel R and the blue pixel B is set, and then the optical path length of the green pixel G is adjusted by the embossings which are formed in the surface of the overcoating film 180 of the green pixel G.

Because the embossings are formed in a surface of the overcoating film 180 of the green pixel G, the semi-transparent member 193, the pixel electrode 191G, the organic emission layer 370 and the common electrode 270 which are stacked in the green pixel G also have flexures. Therefore, light which is emitted from the organic emission layer 370 is discharged to the outside after sequentially passing through the pixel electrode 191G, the overcoating film 180, the green filter 230G, and the substrate 110. The discharged light forms a predetermined angle θ_{G} from light which is vertically emitted to the substrate 110. Due to the tilt angle θ_{G} of the embossings, the path difference of light in the green wavelength region is changed.

The path difference in the green wavelength region is represented by Equations (4) and (5):

path difference=2nd′ cos θ_{G} (4)

path difference=λ/2 (5)

where n is a refractive index of an organic emission layer, d″ is an actual optical path length, θ_{G} is a tilt angle of embossings, and λ is a green wavelength region.

When rearranging Equations (4) and (5), a wavelength which is amplified by constructive interference in a green wavelength region is represented by Equation (6).

λ=4nd′ cos θ_{G} (6)

However, in consideration of a tilt angle θ_{G} by embossings, an actual optical path length d′ is represented by Equation (7) using a normal length d between the common electrode 270 and the semi-transparent member 193.

d′=d cos θ_{G} (7)

When rearranging Equations (6) and (7), Equations (6) and (7) are represented by Equation (8).

λ=4nd cos² θ_{G} (8)

Referring to Equation (8), it can be seen that a wavelength of light which is amplified by constructive interference is varied with the tilt angle θ_{G} of the embossings, i.e., proportional to the square of the cosine of the tilt angle θ_{G}.

Therefore, in the green pixel G, a microcavity condition can be set by adjusting the tilt angle of the embossings in a green wavelength region.

In an exemplary embodiment, the embossings can be formed in the green, red and blue pixel regions with different tilt angles. For example, the embossings can be formed in such a way that the tilt angle of the embossings formed in the green pixel is greater than that of the embossings formed in the red pixel and the blue pixel. Details thereon are further described hereinafter.

When exposing the overcoating film 180, the tilt angle θ_{G} can be adjusted by varying an exposure amount. When the exposure amount is large, because an exposure depth increases in a surface of the overcoating film 180, the tilt angle θ_{G} increases, and when the exposure amount is less, because the exposure depth decreases, the tilt angle θ_{G} decreases.

As another method, the tilt angle θ_{G} may be adjusted by varying an opening size of a exposure mask used when exposing the overcoating film 180.

The color shift may be described by a phenomenon in which a color looks different as a peak wavelength of a light emitting spectrum which is seen from the side view moves toward a short wavelength or a long wavelength, compared with a peak wavelength of a light emitting spectrum which is seen from the front view. The color shift is very large in light of a green wavelength region in the white light which is emitted from the organic emission layer 370. Because light of a red wavelength region in the white light which is emitted from the organic emission layer 370 is not significantly changed by a peak wavelength of a light emitting spectrum according to the change of a microcavity condition, the color shift is not very high. In light of a blue wavelength region, because the phenomenon in which the spectrum moves to a short wavelength according to a viewing angle is limited due to a cut-off phenomenon occurring at a region of about 450 nm or less, the color shift is also not very significant.

Therefore, in the present exemplary embodiment, after a microcavity condition simultaneously satisfying a constructive interference condition is set in the red pixel R and the blue pixel B, a microcavity condition in the green pixel G can be set by adjusting a tilt angle of embossings in the green pixel G, thereby mitigating the color shift.

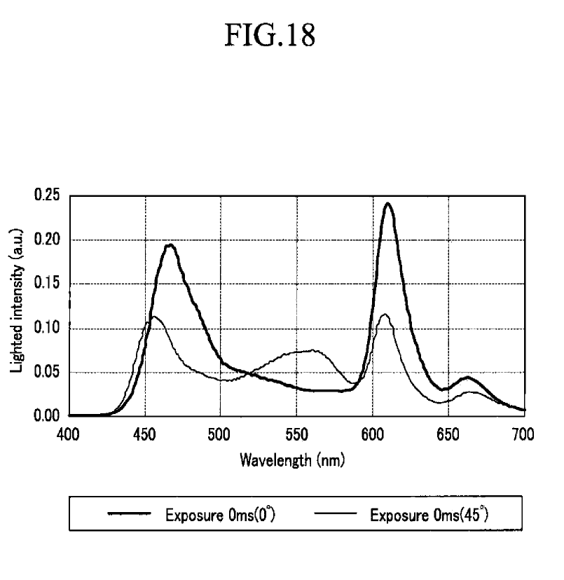

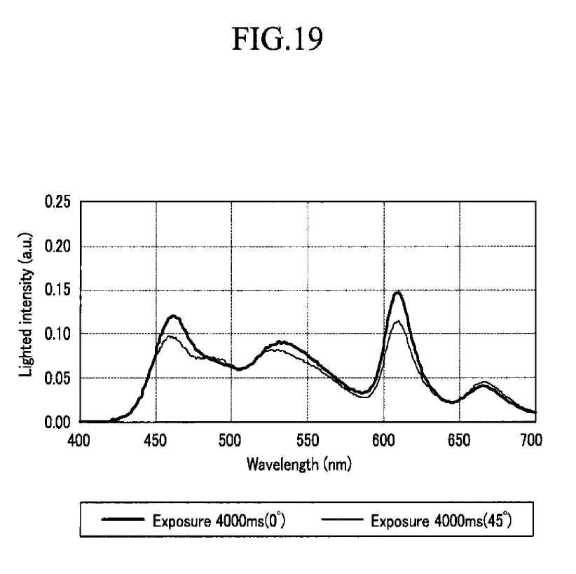

This is described with reference to FIGS. 18 and 19.

FIG. 18 is a graph illustrating a light emitting spectrum in a front view and a side view of a red pixel R and a blue pixel B in an OLED display according to an exemplary embodiment of the present invention. FIG. 19 is a graph illustrating a light emitting spectrum in a front view and a side view of a green pixel G in an OLED display according to an exemplary embodiment of the present invention.

Referring to FIG. 18, it can be seen that, with respect to light of a red region (about 610 nm) and light of a blue region (about 460 nm), a difference between peak wavelengths in the front view (thick line) and the side view (thin line) is not significant even if embossings are not formed in such pixel regions. Referring to FIG. 19, it can also be seen that a difference between peak wavelengths in the front view (thick line) and the side view (thin line) is not significant with respect to light of a green region (about 530 nm), due to the embossings formed in the green pixel G.

This is because when light which is emitted from the organic emission layer 370 is repeatedly reflected between the semi-transparent member 193 and the common electrode 270, the light is reflected in several directions by embossings and is seen with the same condition regardless of a specific direction due to scattering of the light which is reflected in several directions. Accordingly, because light of the same wavelength region is emitted regardless of a viewing angle, a color shift according to a viewing angle can be prevented.

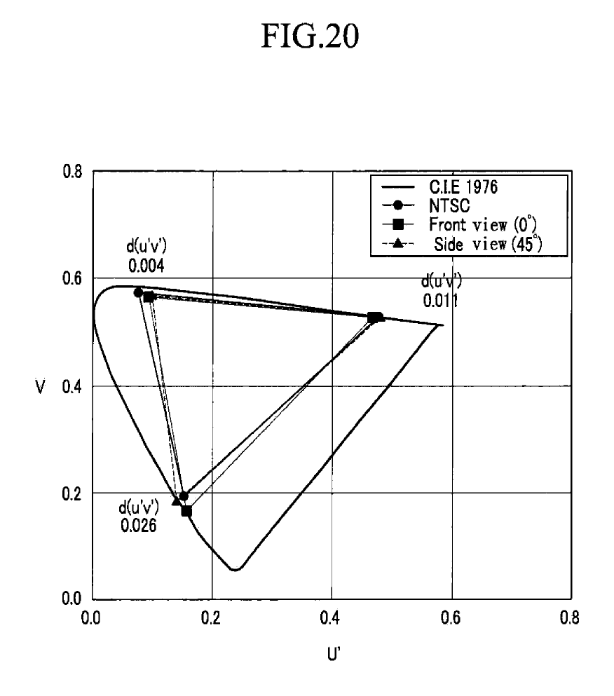

FIG. 20 is a graph illustrating color reproducibility of an OLED display according to an exemplary embodiment of the present invention, using a C.I.E 1976 chromacity diagram.

Referring to FIG. 20, when a semi-transparent member and embossings in the green pixel G are employed, color reproducibility is about 97% of NTSC in case of the front view and about 99% of NTSC in case of the side view. It can be seen from this result that the change in the color reproducibility between the front view and the side view is remarkably reduced when using a semi-transparent member, as compared with a conventional case where the color reproducibility between the front view and side views is changed by about 30-40%.

Further, the color shift d(u′v′) in a red region, a green region, and a blue region can be represented by a numerical value. In FIG. 20, numerical values of the color shift d(u′v′) in the red region, the green region, and the blue region are about 0.011, 0.004 and 0.026 respectively. It can be seen from this result that the color shift is remarkably reduced when using a semi-transparent member and embossings in the green pixel G, as compared with a conventional case where the color shift is about 0.07 to 0.09.

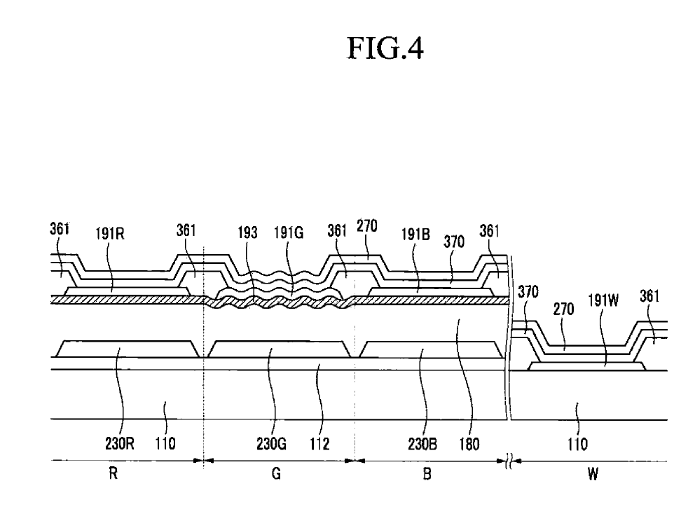

Another exemplary embodiment of the present invention is described with reference to FIG. 4.

Referring to FIG. 4 is a cross-sectional view illustrating an OLED display according to another exemplary embodiment of the present invention.

In the OLED display of this exemplary embodiment, structures of the red pixel R, the green pixel G, and the blue pixel B are the same as in the previous embodiment, but the structure of the white pixel W is different.

In the present exemplary embodiment, in the white pixel W, the overcoating film 180 and the lower insulating layer 112 are not formed. As can be seen in the above-described exemplary embodiment, the white pixel W is irrelevant to a microcavity effect, unlike the red pixel R, the blue pixel B, and the green pixel G. Therefore, because the white pixel W does not include the semi-transparent member 193 and the color filter, the overcoating film 180 and the lower insulating layer 112 may also be omitted.

By removing the overcoating film 180 and the lower insulating layer 112, because light which is emitted from an organic emission layer 370 is discharged to the outside after passing through the pixel electrode 191W and the substrate 110. Thus, light deformation due to a refractive index of each thin film when passing through a plurality of other thin films can be prevented so that intrinsic white light can be emitted. Further, by reducing an amount of light which is absorbed by each thin film among light which is emitted from the organic emission layer, light emitting efficiency can also be improved. Also, damage to the overcoating film 180 due to gases being generated when etching the semi-transparent member 193 can be mitigated.

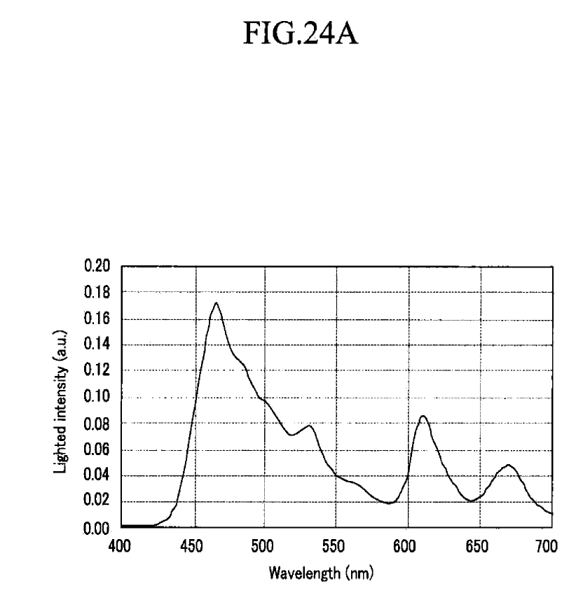

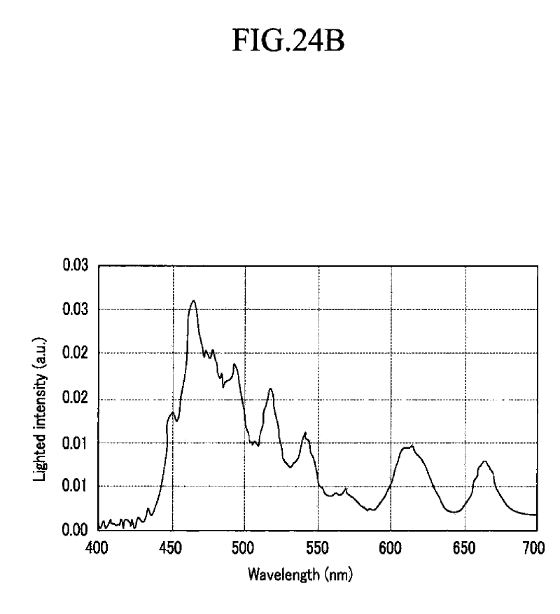

This exemplary embodiment is further described with reference to FIGS. 24A and 24B.

FIG. 24A is a graph illustrating a spectrum of light passing through a white pixel W when an overcoating film 180 and a lower insulating layer 112 are formed in the white pixel W according to an exemplary embodiment of the present invention. FIG. 24B is a graph illustrating a spectrum of light passing through a white pixel W when an overcoating film 180 and a lower insulating layer 112 are not formed in the white pixel W according to an exemplary embodiment of the present invention.

Referring to FIGS. 24A and 24B, when omitting the overcoating film 180 and the lower insulating layer 112 according to the present exemplary embodiment, it can be seen that color purity and color reproducibility on wavelength of visible rays increase, and that transmittance improves in each wavelength region, and thus light emitting efficiency can be improved.

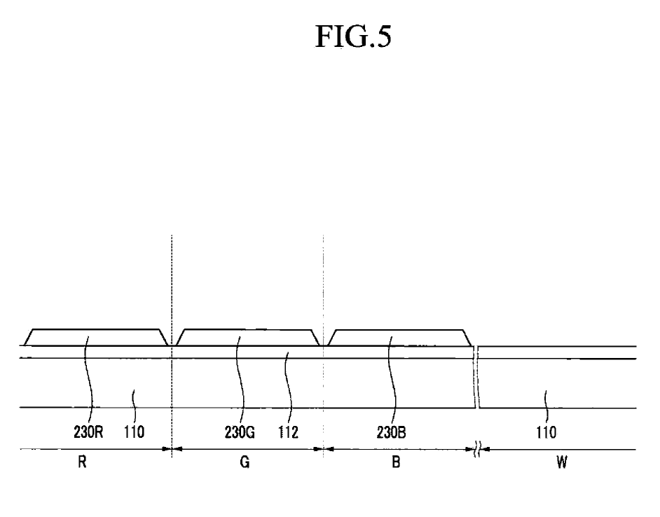

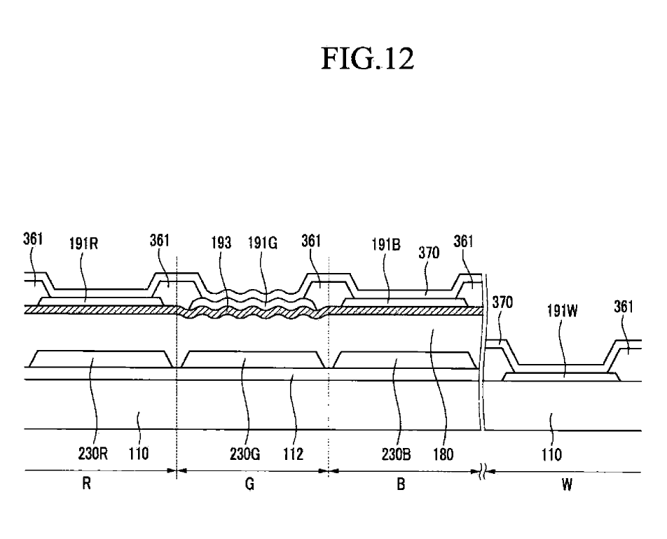

A method of manufacturing an OLED display according to the present exemplary embodiment is described hereinafter with reference to FIGS. 5 to 12.

FIGS. 5 to 12 are cross-sectional views sequentially illustrating a method of manufacturing the OLED display of FIG. 4 according to an exemplary embodiment of the present invention.

Referring to FIG. 5, a plurality of switching thin film transistors (not shown) and a plurality of driving thin film transistors (not shown) are formed on the insulating substrate 110. A conductive layer, an insulating layer, and a semiconductor layer are formed and patterned on the switching thin film transistor and a driving thin film transistor.

Thereafter, a lower insulating layer 112 is formed on the switching thin film transistor and the driving thin film transistor, and then a plurality of color filters 230R, 230G, and 230B are formed on the lower insulating layer 112.

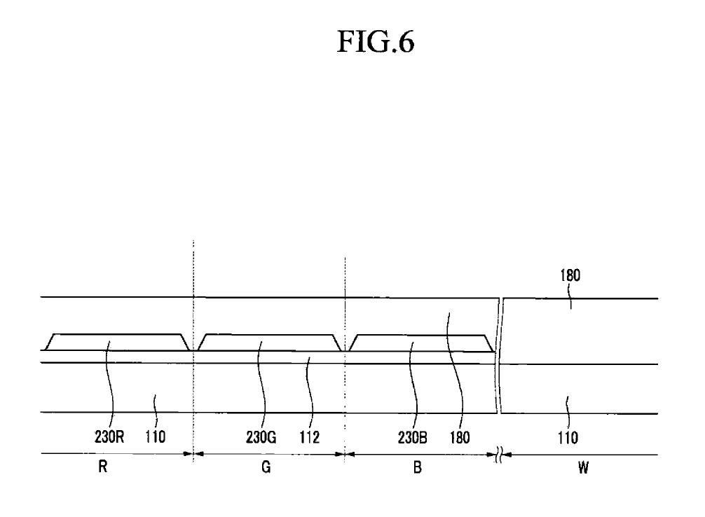

Next, referring to FIG. 6, an overcoating film 180 is coated on the lower insulating layer 112 and the color filters 230R, 230G, and 230B.

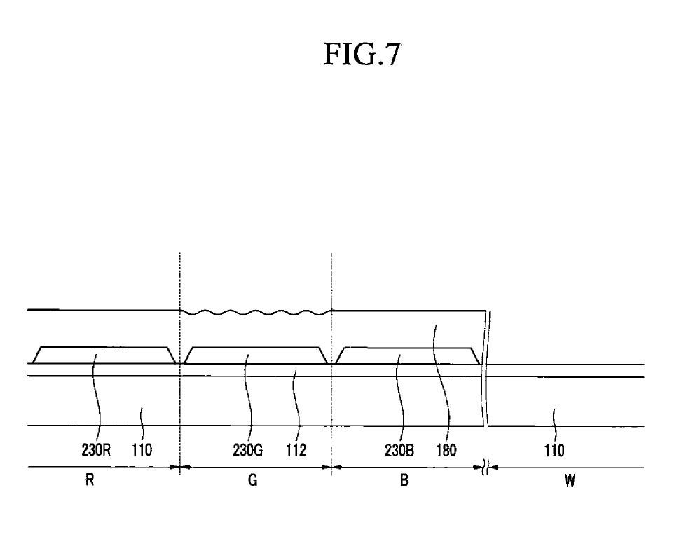

Referring to FIG. 7, an exposure mask (not shown) is disposed on the overcoating film 180 and the overcoating film 180 is exposed. Here, the overcoating film 180 of the white pixel W is removed and a plurality of contact holes (not shown) are formed in each pixel, and at the same time, embossings are formed in the surface of the overcoating film 180 of the green pixel G.

The removing of the overcoating film 180 of the white pixel W, the forming of a plurality of contact holes, and the forming of embossings can be performed simultaneously using the exposure mask having openings which completely transmit light and semi-transparent portions which transmit only a part of light. For example, the exposure mask can have openings corresponding to a size of the white pixel W at positions corresponding to the white pixel W and openings at a position corresponding to a contact hole of each pixel. Further, the exposure mask can be designed to have semi-transparent portions at positions corresponding to green pixels G in which embossings are formed. The semi-transparent part may be formed to have a plurality of slits or microholes.

Thereafter, exposure is performed by radiating: light such as ultraviolet rays (UV) on the exposure mask. The exposure amount can be determined according to the tilt angle of embossings.

Thereafter, by removing the exposure mask and performing heat treatment of the overcoating film 180, embossings of the green pixel G form soft flexures.

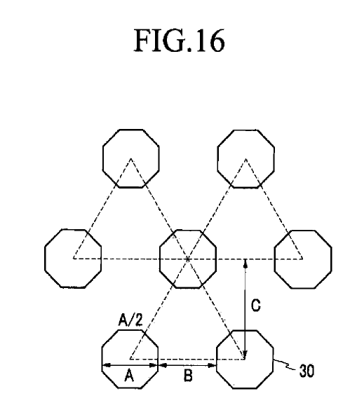

FIG. 16 is a schematic diagram illustrating a plurality of microholes which are formed in a semi-transparent unit of a mask.

Referring to FIG. 16, the microholes 30 can have a plurality of polygonal shapes. In this case, the semi-transparent layer can be designed in consideration of a size A of a microhole 30, an interval B between neighboring microholes 30, and an interval C from the central part of the microhole 30 to a predetermined position. For example the size A, the interval B, and the interval C may be about 3 μm, 2 μm, and 4.25 μm, respectively. As the size of the microholes 30 increases, an exposure depth of the overcoating film 180 increases and thus a tilt angle θ_{G} of embossings increases, and as the size of the microholes 30 decreases, an exposure depth of the overcoating film 180 decreases and thus a tilt angle θ_{G} of embossings decreases.

As another method, by changing an exposure amount, the tilt angle θ_{G} of embossings can be adjusted.

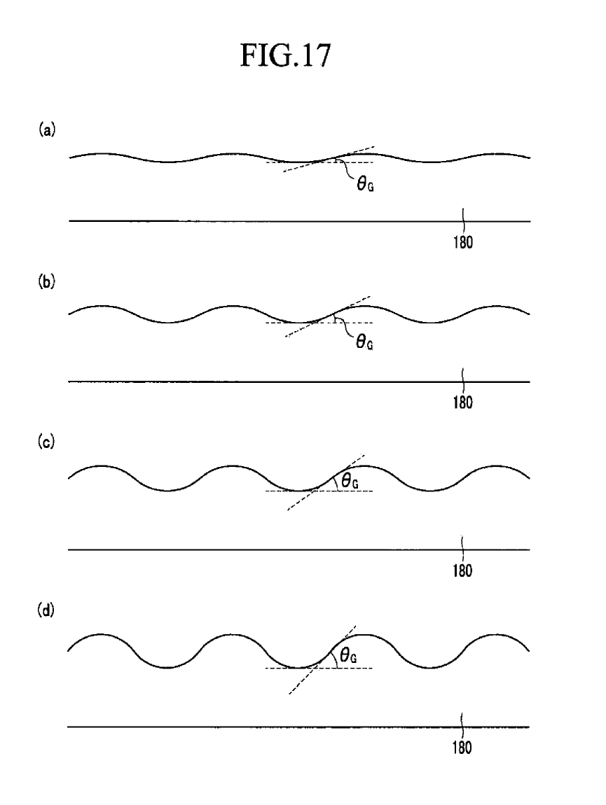

FIG. 17 is a diagram illustrating the change of a tilt angle θ_{G} of embossings according to an exposure amount.

FIG. 17, (a), (b), (c) and (d) show tilt angles θ_{G} of embossings when exposure amounts are about 2000 ms, about 3000 ms, about 4000 ms, and about 5000 ms, respectively. It can be seen that as an exposure amount increases, the tilt angle θ_{G} of embossings increases.

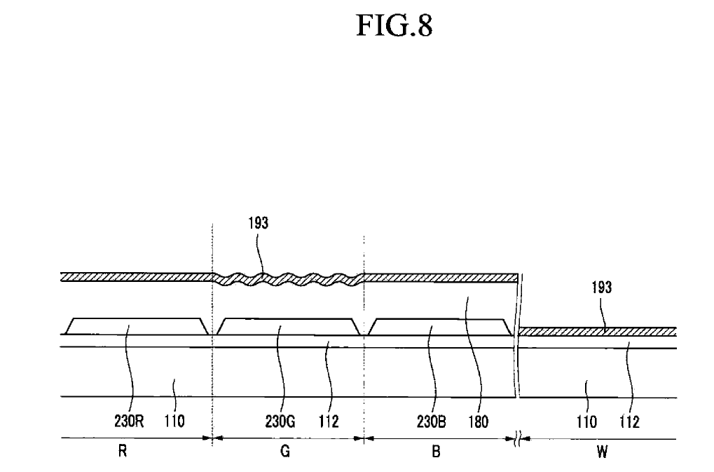

Next, referring to FIG. 8, a semi-transparent member 193 is formed on the overcoating film 180 and the lower insulating layer 112. The semi-transparent member 193 can be formed in a plurality of layers by alternately and repeatedly stacking silicon oxide and silicon nitride. The semi-transparent member 193 can be formed with a chemical vapor deposition (CVD) method, and in this case, by performing chemical vapor deposition at a relatively low temperature of about 200° C., the overcoating film 180 which is positioned at a lower part thereof can be prevented from being damaged.

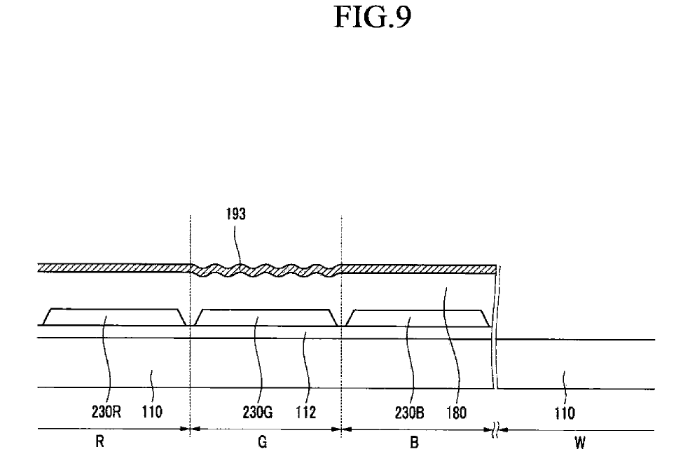

Next, referring to FIG. 9, the semi-transparent member 193 and the lower insulating layer 112 which are formed in the white pixel W are removed. Further, in this step, a plurality of contact holes (not shown) are formed in each pixel.

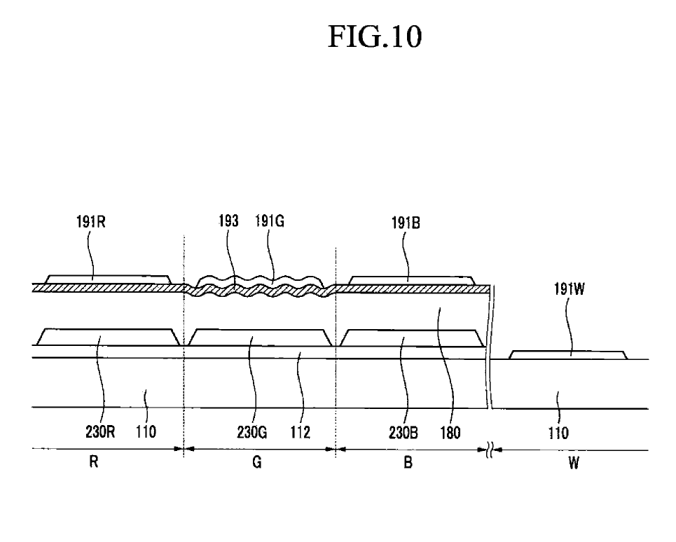

Next, referring to FIG. 10, by forming a transparent conductive layer on the semi-transparent member 193 and the substrate 110 and performing a photolithography process, pixel electrodes 191R, 191G, 191B, and 191W are formed in each pixel.

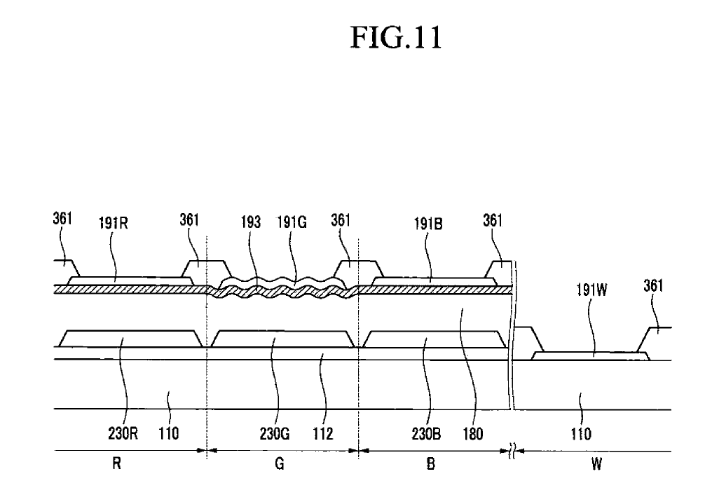

Next, referring to FIG. 11, an insulating layer 361 is formed by coating on the pixel electrodes 191R, 191G, 191B, and 191W and the semi-transparent member 193 and patterning them.

Thereafter, an emission layer 370, in which a red emission layer (not shown), a blue emission layer (not shown), and a green emission layer (not shown) are sequentially stacked, is formed on the entire surface of the substrate.

Thereafter, a common electrode 270 is formed on the emission layer 370.

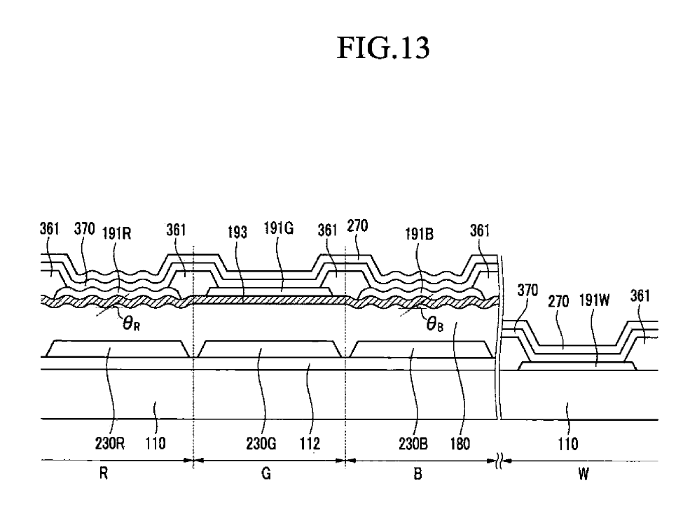

Another exemplary embodiment of the present invention is described with reference to FIG. 13.

FIG. 13 is a cross-sectional view illustrating an OLED display according to another exemplary embodiment of the present invention.

Alternatively, the above-described exemplary embodiment, in an OLED display device according to an exemplary embodiment, embossings are not formed in a surface of the overcoating film 180 in the green pixel G, but embossings are formed in surfaces of the red pixel R and the blue pixel B.

That is, after setting a microcavity condition which satisfies a constructive interference condition of the green pixel G, an optical path length can be adjusted by forming embossings in the red pixel R and the blue pixel B. In this case, by setting a tilt angle θ_{R} of embossings in the red pixel R and a tilt angle θ_{B} of embossings in the blue pixel B to be substantially equal, the processes can be simplified.

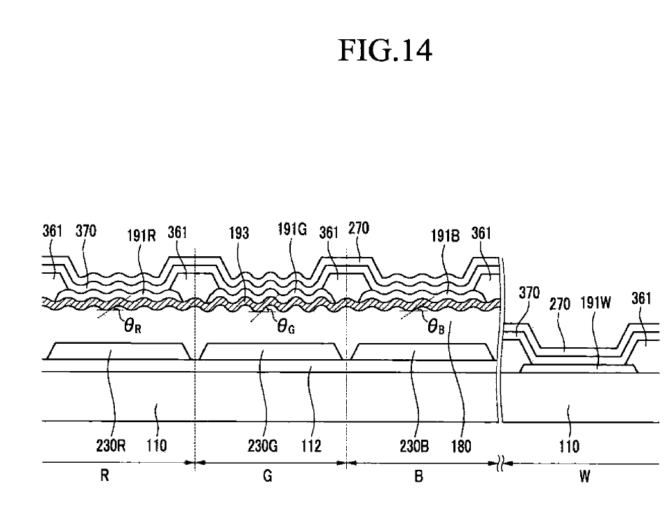

Another exemplary embodiment of the present invention is described with reference to FIG. 14.

FIG. 14 is a cross-sectional view illustrating an OLED display according to another exemplary embodiment of the present invention.

An OLED display device according to the current exemplary embodiment has embossings in all of a red pixel R, a green pixel G, and a blue pixel B. However, by forming a tilt angle θ_{G} of the green pixel G to be greater than tilt angles (θ_{R}, θ_{B}) of the red pixel R and the blue pixel B, a microcavity condition can be optimized.

As described above, the tilt angle can be adjusted using an exposure amount when exposing the overcoating film 180 or by using an exposure mask having different opening sizes.

By forming embossings in the red pixel R and the blue pixel B as well as the green pixel G, a color shift which is slightly generated in the red pixel R and the blue pixel B can also be prevented.

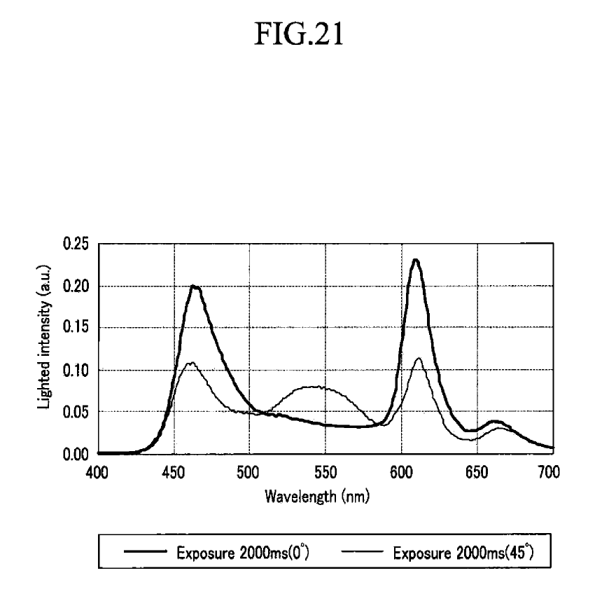

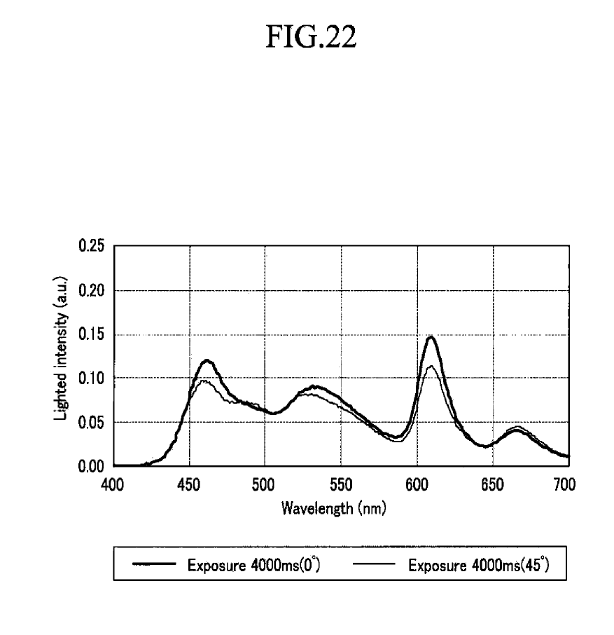

FIG. 21 is a graph illustrating a light emitting spectrum at a front view and a side view of a red pixel R and a blue pixel B in an OLED display according to this exemplary embodiment of the present invention. FIG. 22 is a graph illustrating a light emitting spectrum in a front view and a side view of a green pixel G in an OLED display according to this exemplary embodiment of the present invention.

Referring to FIG. 21, when embossings of predetermined tilt angles (θ_{R}, θ_{B}) are formed with an exposure amount of about 2000 ms in the red pixel R and the blue pixel B, it can be seen that the change of a peak wavelength of light of a red region (about 610 nm) and light of a blue region (about 460 nm) is further reduced at the front view and the side view, as compared with the case of previous exemplary embodiment. Further, referring to FIG. 22, it can be seen that the change of a peak wavelength of light of a green region (about 530 nm) is not very large at the front view and the side view, as in the case of previous exemplary embodiment.

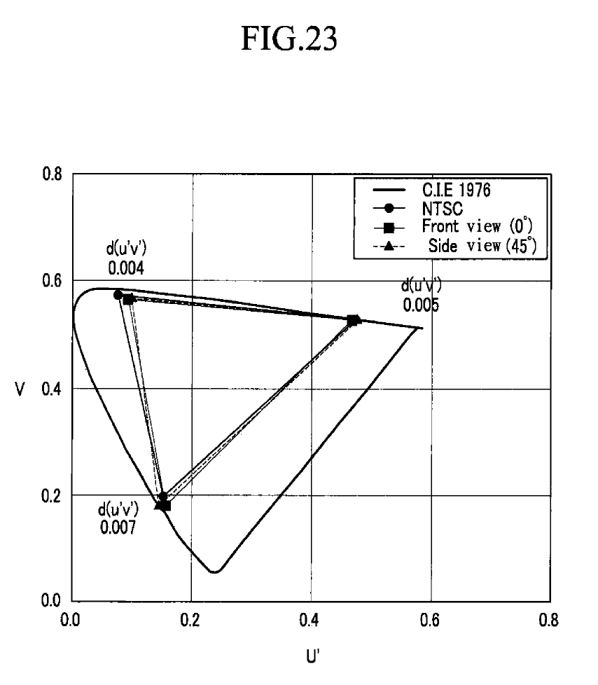

FIG. 23 is a graph illustrating color reproducibility of an OLED display according to another exemplary embodiment of the present invention with a C.I.E 1976 color coordinate.

Referring to FIG. 23 showing the C.I.E 1976 chromacity diagram, when observing color reproducibility using a semi-transparent member, white light, and a color filter, the color reproducibility is about 98% of the NTSC at the front view and about 96% of the NTSC at the side view. It can be seen from FIG. 23 that the change of color reproducibility between the front view and the side view is remarkably reduced when using a semi-transparent member, as compared with a conventional case where color reproducibility decreases by about 30-40% of NTSC.

Further, when considering a color shift d(u′v′) in a red region, a green region, and a blue region with a numerical value, it can be seen from FIG. 23 that the color shift in the red region, the green region, and the blue region are about 0.005, 0.004, and 0.007, respectively. It can be seen that the color shift can be remarkably reduced when using the semi-transparent member, as compared with a conventional case where a degree of a color shift is about 0.07 to 0.09. Also, the color shift is remarkably reduced in a red region and a blue region, as compared with previous exemplary embodiment.

While the present invention has been shown and described with reference to some exemplary embodiments thereof, it should be understood by those of ordinary skill in the art that various changes in form and details may be made therein without departing from the spirit and scope of present invention as defined by the appending claims.

What is claimed is:

1. An organic light emitting diode (OLED) display device comprising a plurality of pixels, the display device comprising:
a first electrode;
a second electrode which is opposite to the first electrode;
an emission layer which is disposed between the first electrode and the second electrode;
a semi-transparent member which forms a microcavity together with the second electrode; and
an overcoating film that is positioned under the semi-transparent member,
wherein the pixel includes embossings formed in a surface of the semi-transparent member, the embossings forming a flexural surface having a tilt angle.

2. The OLED display device of claim 1, wherein the pixel includes a green pixel, a blue pixel and a red pixel.

3. The OLED display device of claim 2, wherein the embossings are formed in the green pixel.

4. The OLED display device of claim 2, wherein the embossings are formed in the red pixel and the blue pixel.

5. The OLED display device of claim 2, wherein the embossings are formed in the green pixel, the red pixel and the blue pixel, and the tilt angle of the embossings formed in the green pixel is different from that of that embossings formed in the red pixel and the blue pixel.

6. The OLED display device of claim 5, wherein the tilt angle of the embossings formed in the green pixel is greater than that of the embossings formed in the red pixel and the blue pixel.

7. The OLED display device of claim 5, wherein the embossings formed in the red pixel and in the blue pixel have substantially identical tilt angles.

8. The OLED display device of claim 1, wherein the emission layer includes a plurality of sub-emission layers which emit lights of different wavelengths and emits white light by combining the lights of the different wavelengths.

9. The OLED display device of claim 8, further comprising a color filter that is formed under the first electrode.

10. The OLED display device of claim 1, wherein the semi-transparent member comprises N number of layers including a first layer and a second layer alternately stacked, the first and second layers having different refractive indexes.

11. The OLED display device of claim 10, wherein the semi-transparent member has a substantially uniform thickness in each of the plurality of pixels, and the thicknesses of the first layer and the second layer in N−1 number of layers are λ/4n₁ and λ/4n₂, respectively (n₁ is a refractive index of the first layer, n₂ is a refractive index of the second layer, and λ is a wavelength of a green region).

12. The OLED display device of claim 11, wherein the first layer comprises silicon oxide (SiO₂), and the second layer comprises silicon nitride (SiNₓ).

13. The OLED display device of claim 10, wherein the semi-transparent member has a substantially uniform thickness in each of the plurality of pixels, and
when a gap between the second electrode and the semi-transparent member is an optical path length (L), the optical path length is the smallest value among values satisfying both L=m₁λ₁/2 and L=m₂λ₂/2 (λ₁ is a wavelength of a red region, λ₂ is a wavelength of a blue region, and m₁ and m₂ are natural numbers).

14. The OLED display device of claim 2, wherein the pixel further includes a white pixel,
wherein the overcoating film is not formed in the white pixel.

15. A method of manufacturing an OLED display device comprising a plurality of pixels, the method comprising:
forming a plurality of thin film transistors on a substrate;
forming an overcoating film on the substrate and the thin film transistor;
forming embossings in a surface of the overcoating film, the embossings having a tilt angle;
forming a semi-transparent member on the overcoating film;
forming a first electrode on the semi-transparent member;
forming an emission layer on the first electrode; and
forming a second electrode on the emission layer.

16. The method of claim 15, wherein the forming of embossings in a surface of the overcoating film comprises:
disposing a mask having an opening on the overcoating film and exposing; and
performing heat treatment of the exposed overcoating film.

17. The method of claim 16, wherein the pixel includes a green pixel, a red pixel and a blue pixel.

18. The method of claim 17, wherein the embossings are formed in the green pixel.

19. The method of claim 17, wherein the embossings are formed in the red pixel and the blue pixel.

20. The method of claim 17, wherein the embossings are formed in the green pixel, the red pixel, and the blue pixel, and the tilt angle of embossings formed in the green pixel is different from that of the embossings formed in the red pixel and the blue pixel.

21. The method of claim 16, wherein the tilt angle is adjusted by varying an exposure amount.

22. The method of claim 16, wherein the tilt angle is adjusted by varying the size of openings of the mask.

23. The method of claim 15, wherein the forming of embossings in a surface of the overcoating film comprises forming a contact hole which exposes a part of the thin film transistor in the overcoating film.

24. The method of claim 17, wherein the pixel further comprises a white pixel, and
wherein the forming of embossings in a surface of the overcoating film comprises removing the overcoating film which is formed in the white pixel.

25. A light emitting display device comprising a plurality of pixels, the comprising:
a first electrode;
a second electrode which is opposite to the first electrode;
an emission layer which is disposed between the first electrode and the second electrode; and
a semi-transparent layer which forms a microcavity with the second electrode,
wherein the semi-transparent layer includes a flexural surface, the flexural surface being inclined with respect to the plane of the semi-transparent layer.

26. The display device of claim 25, wherein the pixel includes a green pixel, a blue pixel and a red pixel.

27. The display device of claim 26, wherein the flexural surface is formed in the green pixel.
